(19) United States
(12) Patent Application Publication
(10) Pub. No.: US 2025/0275425 A1
(43) Pub. Date: Aug. 28, 2025

(54) Display Device

(71) Applicant: LG Display Co., Ltd., Seoul (KR)

(72) Inventors: JaeGyun Lee, Paju-si (KR); JiHyun Jung, Paju-si (KR); SuChang An, Paju-si (KR); Ruda Rhe, Paju-si (KR); Hyangmyoung Gwon, Paju-si (KR)

(21) Appl. No.: 18/942,099

(22) Filed: Nov. 8, 2024

(30) Foreign Application Priority Data
Feb. 22, 2024 (KR) 10-2024-0025671

(51) Int. Cl. H10K 59/80; H10K 59/122; H10K 59/40

(52) U.S. Cl. CPC H10K 59/873; H10K 59/122; H10K 59/40

(57) ABSTRACT

Embodiments of the present disclosure relate to a display device. A display device may include a substrate including a display area and a non-display area, a first planarization layer disposed on the substrate, a second planarization layer disposed on the first planarization layer, a bank disposed on the second planarization layer, a first encapsulation layer disposed on the bank, a touch sensor disposed on the first encapsulation layer, a second encapsulation layer disposed on the touch sensor, and a first outer dam disposed on an outer side of the second encapsulation layer, and including at least one of the first planarization layer, the second planarization layer, and the bank, thereby reducing the bezel size.

### CROSS REFERENCE TO RELATED APPLICATION

This application claims priority from Republic of Korea Patent Application No. 10-2024-0025671, filed on Feb. 22, 2024, which is hereby incorporated by reference in its entirety.

### TECHNICAL FIELD

Embodiments of the present disclosure relate to a display device.

### BACKGROUND

As the information society develops, there is increasing the demand for display devices for displaying images in various forms. Therefore, in recent years, there have been used various display devices such as liquid crystal displays and organic light emitting display devices.

A display device may include a display area and a non-display area.

The non-display area may be also referred to as a bezel.

### SUMMARY

Embodiments of the present disclosure may provide a display device including an outer dam capable of reducing a bezel size.

Embodiments of the present disclosure may provide a display device capable of preventing or at least reducing an organic encapsulation layer from overflowing through an outer dam.

Embodiments of the present disclosure may provide a display device capable of preventing crack formation by using an outer dam.

Embodiments of the present disclosure may provide a display device capable of increasing process efficiency by using an outer dam functioning as a dam and a crack stopper.

Embodiments of the present disclosure may provide a display device including a substrate including a display area and a non-display area, a first planarization layer disposed on the substrate, a second planarization layer disposed on the first planarization layer, a bank disposed on the second planarization layer, a first encapsulation layer disposed on the bank, a touch sensor disposed on the first encapsulation layer, a second encapsulation layer disposed on the touch sensor, and a first outer dam disposed on an outer side of the second encapsulation layer, and including at least one of the first planarization layer, the second planarization layer, and the bank.

The first outer dam may further include the bank, and a protective layer disposed on the bank.

The display device according to embodiments of the present disclosure may further include a second outer dam disposed in contact with the second encapsulation layer on the outer side of the second encapsulation layer. A height of the first outer dam may be greater than a height of the second outer dam.

The substrate may include a first non-display area on which a plurality of pads are disposed, and a second non-display area different from the first non-display area. In addition, the first outer dam disposed in the second non-display area may include at least one of a first planarization layer, a second planarization layer, and a bank, and the first outer dam disposed in the first non-display area may include a protective layer.

The second encapsulation layer may be an organic insulating film. The second encapsulation layer may include one of acrylic resin, epoxy resin, polyimide, polyethylene, or siliconoxycarbon.

The second encapsulation layer may be formed through an inkjet process.

According to embodiments of the present disclosure, it is possible to provide a display device including an outer dam capable of reducing a bezel size.

According to embodiments of the present disclosure, it is possible to provide a display device capable of preventing an organic encapsulation layer from overflowing through an outer dam.

According to embodiments of the present disclosure, it is possible to provide a display device capable of preventing crack formation by using an outer dam.

According to embodiments of the present disclosure, it is possible to provide a display device capable of increasing process efficiency by using an outer dam functioning as a dam and a crack stopper.

### BRIEF DESCRIPTION OF THE DRAWINGS

FIG. 1 is a system configuration diagram of a display device according to embodiments of the present disclosure.

FIG. 2 illustrates a display panel according to embodiments of the present disclosure.

FIG. 3 illustrates a substrate of a display panel according to embodiments of the present disclosure.

FIG. 4 is a cross-sectional view of a display area of a display panel according to embodiments of the present disclosure.

FIGS. 5, 6, and 7 are cross-sectional views of a display panel including inner dams and outer dams according to embodiments of the present disclosure.

### DETAILED DESCRIPTION

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

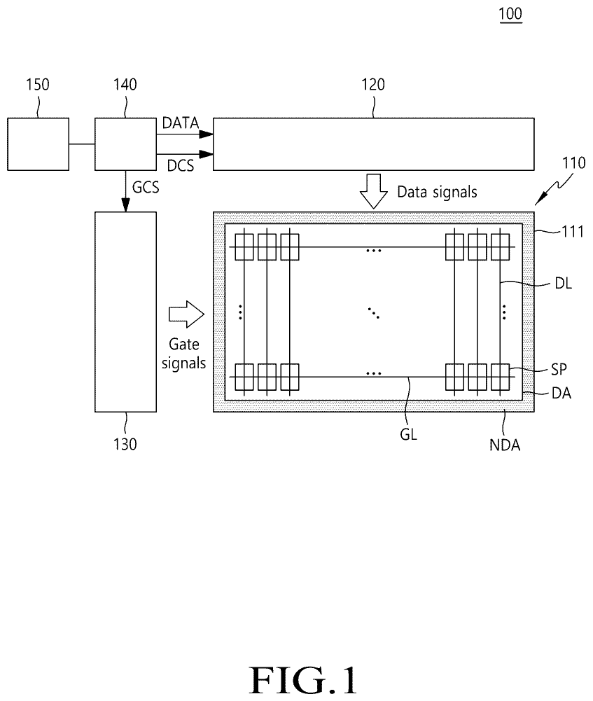

FIG. 1 is a system configuration diagram of a display device 100 according to embodiments of the present disclosure.

Referring to FIG. 1, a display device 100 according to embodiments of the present disclosure may include a display panel 110 and a display driving circuit as components for displaying an image. The display driving circuit is a circuit for driving the display panel 110, and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA located outside the display area DA.

A plurality of subpixels SP for image display may be disposed in the display area DA, and the non-display area NDA may include a pad area PA located in the first direction from the display area DA

In a display panel 110 according to embodiments of the present disclosure, the non-display area NDA may be very small. In this specification, the non-display area NDA may be also referred to as a “bezel.”

For example, the non-display area NDA may include a first non-display area located outside the display area DA in a first direction, a second non-display area located outside the display area DA in a second direction intersecting the first direction, a third non-display area located outside the display area DA in the opposite direction to the first direction, and a fourth non-display area located outside the display area DA in the direction opposite to the second direction. One or both of the first to fourth non-display areas may include a pad area to which the data driving circuit 120 is connected or bonded. Among the first to fourth non-display areas, two or three which do not include the pad area may be very small in size.

For another example, a boundary area between the display area DA and the non-display area NDA may be bent so that the non-display area NDA may be located below the display area. In this case, when the user looks at the display device 100 from the front, there may be little or no non-display area NDA visible to the user.

Various types of signal lines for driving a plurality of subpixels SP may be disposed on the substrate 111 of the display panel 110.

The display device 100 according to embodiments of the present disclosure may be a liquid crystal display device or the like, or may be a self-luminous display device in which the display panel 110 emits light by itself. When the display device 100 according to embodiments of the present disclosure is a self-luminous display device, each of the plurality of subpixels SP may include a light emitting device.

For example, the display device 100 according to embodiments of the present disclosure may be an organic light emitting display device in which a light emitting device is implemented as an organic light emitting diode (OLED). For another example, the display device 100 according to embodiments of the present disclosure may be an inorganic light emitting display device in which the light emitting device is implemented as an inorganic-based light emitting diode. For another example, the display device 100 according to embodiments of the present disclosure may be a quantum dot display device in which a light emitting device is implemented with quantum dots, which are semiconductor crystals emitting light by itself.

The structure of each of the plurality of subpixels SP may vary depending on the type of the display device 100. For example, if the display device 100 is a self-luminous display device with the subpixel SP emitting light by itself, each subpixel SP may include a self-luminous light emitting device, one or more transistors, and one or more capacitors.

For example, various types of signal lines may include a plurality of data lines DL supplying data signals (also called data voltages or image signals) and a plurality of gate lines GL for transmitting gate signals (also called scan signals).

For example, the plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will exemplified a case in which each of the plurality of data lines DL is arranged in a column direction, and each of the plurality of gate lines GL is arranged in a row direction.

The data driving circuit 120 is a circuit for driving a plurality of data lines DL, and may output data signals to the plurality of data lines DL.

The data driving circuit 120 may receive image data in digital form from the display controller 140 and convert the received image data into analog data signals to output to a plurality of data lines DL.

For example, the data driving circuita 120 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The data driving circuit 120 may be connected to one side (e.g., the upper or lower side) of the display panel 110. Depending on the driving method, panel design method, etc., the data driving circuit 120 may be connected to both sides (e.g., upper and lower sides) of the display panel 110, or may be connected to two or more of the four sides of the display panel 110.

The data driving circuit 120 may be connected to the outside of the display area DA of the display panel 110, but alternatively, it may be disposed in the display area DA of the display panel 110.

The gate driving circuit 130 is a circuit for driving a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

In the display device 100 according to embodiments of the present disclosure, the gate driving circuit 130 may be built into the display panel 110 as a gate-in-panel (GIP) type. If the gate driving circuit 130 is a gate-in-panel type, the gate driving circuit 130 may be formed on a substrate of the display panel 110 during the manufacturing process of the display panel 110.

In the display device 100 according to embodiments of the present disclosure, the gate driving circuit 130 may be disposed in the display area DA of the display panel 110. For example, the gate driving circuit 130 may be disposed in a first partial area within the display area DA (e.g., a left area or a right area within the display area DA). For another example, the gate driving circuit 130 may be disposed in a first partial area within the display area DA (e.g., a left area or a right area within the display area DA) and a second partial area (e.g., a right area or a left area within the display area DA).

In the present disclosure, a gate driving circuit 130 built into the display panel 110 as a gate-in-panel type may be referred to as a “gate-in-panel circuit.”

The display controller 140 may be a device for controlling the data driving circuit 120 and the gate driving circuit 130, and may control the driving timing for the plurality of data lines DL and the driving timing of the plurality of gate lines GL.

The display controller 140 may supply a data driving control signal DCS to the data driving circuit 120 to control the data driving circuit 120, and may supply a gate driving control signal GCS to the gate driving circuit 130 to control the gate driving circuit 130.

The display controller 140 may receive input image data from a host system 150 and supply image data DATA to the data driving circuit 120 based on the input image data.

The display controller 140 may be implemented as a separate component from the data driving circuit 120, or may be integrated with the data driving circuit 120 and implemented as an integrated circuit.

The display controller 140 may be a timing controller used in typical display technology, or may be a control device capable of further performing other control functions including a timing controller, or may be a control device different from the timing controller, or may be a control device other than a timing controller, or may be a circuit within the control device. The display controller 140 may be implemented with various circuits or electronic components, such as an integrated circuit (IC), a field programmable gate array (FPGA), an application specific integrated circuit (ASIC), or Processor.

The display controller 140 may be mounted on a printed circuit board, a flexible printed circuit, etc., and may be electrically connected to the data driving circuit 120 and the gate driving circuit 130 through a printed circuit board, a flexible printed circuit.

The display controller 140 may transmit and receive signals with the data driving circuit 120 according to one or more predetermined interfaces. For example, the interface may include a low voltage differential signaling (LVDS) interface, an embedded clock point-point interface (EPI) interface, or a serial peripheral interface (SPI).

In order to provide not only an image display function but also a touch sensing function, the display device 100 according to embodiments of the present disclosure may include a touch sensor and a touch sensing circuit for detecting an occurrenace of a touch by a touch object such as a finger or pen or detection a touch position by sensing the touch sensor.

The touch sensing circuit may include a touch driving circuit for driving and sensing a touch sensor to generate and output touch sensing data, and a touch controller for detecting the occurrence of a touch or detecting the touch position using touch sensing data.

The touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor exists inside the display panel 110, the touch sensor may be formed on the substrate along with signal lines and electrodes related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

If the touch sensing circuit performs touch sensing using a self-capacitance sensing method, the touch sensing circuit may perform touch sensing based on the capacitance between each touch electrode and a touch object (e.g., finger, pen, etc.). According to the self-capacitance sensing method, each of the plurality of touch electrodes may serve as a driving touch electrode and a sensing touch electrode. The touch driving circuit may drive all or part of the plurality of touch electrodes and sense all or part of the plurality of touch electrodes.

If the touch sensing circuit performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and the touch controller included in the touch sensing circuit may be implemented as separate devices or as one device. Additionally, the touch driving circuit and the data driving circuit may be implemented as separate devices or as one device.

The display device 100 may further include a power supply circuit which supplies various types of power to the display driving circuit and/or the touch sensing circuit.

The display device 100 according to embodiments of the present disclosure may be a mobile terminal such as a smart phone or tablet, or a monitor or television of various sizes, but is not limited thereto, and may be a display of various types and sizes capable of displaying information or images.

The display device 100 according to embodiments of the present disclosure may further include an electronic device such as a camera (e.g., image sensor) and a detection sensor. For example, the detection sensor may be a sensor for detecting an object or a human body by receiving light such as infrared, ultrasonic, or ultraviolet rays.

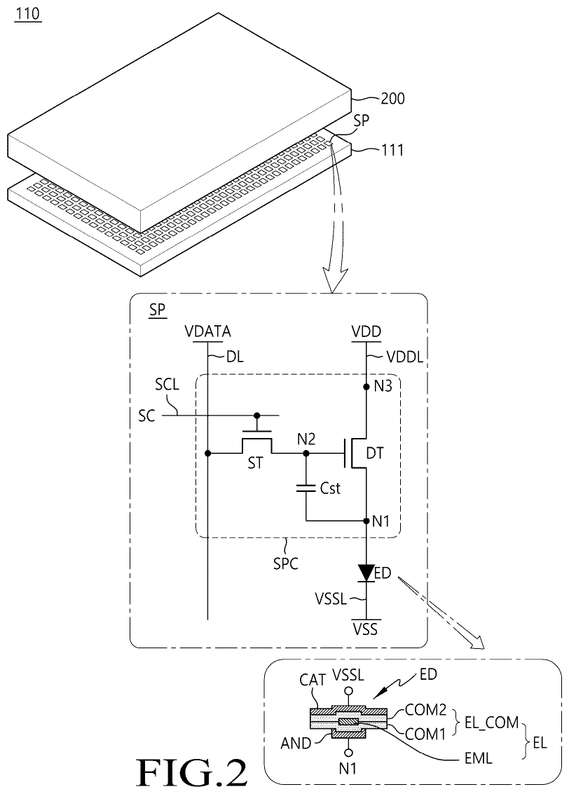

FIG. 2 illustrates a display panel 110 according to embodiments of the present disclosure.

Referring to FIG. 2, the display panel 110 may include the substrate 111 having a plurality of subpixels SP disposed thereon and an encapsulation layer 200 on the substrate 111. Here, the encapsulation layer 200 may also be referred to as an encapsulation substrate or an encapsulation portion.

Referring to FIG. 2, when the display device 100 according to embodiments of the present disclosure is a self-luminous display device, each of the plurality of subpixels SP may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED. In the present disclosure, the subpixel circuit SPC may drive the light emitting device ED by supplying a driving current to the light emitting device ED at a predetermined timing. The light emitting device ED may be driven by a driving current and emit light.

The plurality of pixel driving transistors may include a driving transistor DT for driving the light emitting device ED, and a scan transistor ST which is turned on or off depending on the scan signal SC.

The driving transistor DT may supply driving current to the light emitting device ED.

The scan transistor ST may be configured to control the electrical state of a corresponding node in the subpixel circuit SPC or to control the state or operation of the driving transistor DT.

At least one capacitor may include a storage capacitor Cst to maintain a constant voltage during the frame.

In order to drive the subpixel SP, a data signal VDATA which is an image signal, and a scan signal SC which is a gate signal may be applied to the subpixel SP. In addition, a common pixel driving voltage including a first driving voltage VDD and a second driving voltage VSS may be applied to the subpixel SP in order to drive the subpixel SP.

The light emitting device ED may include an anode AND, a light emitting device intermediate layer EL, and a cathode CAT. The light emitting device intermediate layer EL may be a layer disposed between the anode AND and the cathode CAT.

In the case that the light emitting device ED is an organic light emitting device, the light emitting device intermediate layer EL may include an emission layer EML, a first common intermediate layer COM1 between the anode AND and the emission layer EML, and a second common intermediate layer COM2 between the emission layer EML and the cathode. The emission layer EML may be disposed in each subpixel SP. In comparison, the first common intermediate layer COM1 and the second common intermediate layer COM2 may be commonly disposed across a plurality of subpixels SP. The emission layer EML may be disposed in each emission area, and the first common intermediate layer COM1 and the second common intermediate layer COM2 may be commonly disposed across a plurality of emission areas and non-emission areas. The first common intermediate layer COM1 and the second common intermediate layer COM2 may be collectively referred to as a common intermediate layer EL_COM.

For example, the first common intermediate layer COM1 may include a hole injection layer HIL and a hole transport layer HTL. The second common intermediate layer COM2 may include an electron transport layer ETL and an electron injection layer EIL. The hole injection layer may inject holes from the anode AND to the hole transport layer, the hole transport layer may transport holes to the emission EML, the electron injection layer may inject electrons from the cathode CAT to the electron transport layer, and the electron transport layer may transport electrons to the emission layer EML.

For example, the cathode CAT may be electrically connected to a second common driving voltage line VSSL. A second common driving voltage VSS, which is a type of common pixel driving voltage, may be applied to the cathode CAT through the second common driving voltage line VSSL. The anode AND may be electrically connected to a first node N1 of the driving transistor DT of each subpixel SP. In the present disclosure, the second common driving voltage VSS may also be referred to as a base voltage VSS, and the second common driving voltage line VSSL may also be referred to as a base voltage line VSSL.

For example, the anode AND may be a pixel electrode disposed in each subpixel SP, and the cathode CAT may be a common electrode commonly disposed in a plurality of subpixels SP. For another example, the cathode CAT may be a pixel electrode disposed in each subpixel SP, and the anode AND may be a common electrode commonly disposed in a plurality of subpixels SP. Hereinafter, for convenience of explanation, it is assumed that the anode AND is a pixel electrode and the cathode CAT is a common electrode.

Each light emitting device ED may be composed of overlapping parts of an anode AND, a light emitting device intermediate layer EL and a cathode CAT. A predetermined emission area may be formed by each light emitting device ED. For example, the emission area of each light emitting device ED may include an area where the anode AND, the light emitting device intermediate layer EL and the cathode CAT overlap.

For example, the light emitting device ED may be an organic light emitting diode (OLED), an inorganic light emitting diode, or a quantum dot light emitting device. For example, in the case that the light emitting device ED is an organic light emitting diode OLED, the light emitting device intermediate layer EL in the light emitting device ED may include an organic light emitting device intermediate layer EL containing an organic material.

The driving transistor DT may be a driving transistor for supplying driving current to the light emitting device ED. The driving transistor DT may be connected between a first common driving voltage line VDDL and the light emitting device ED.

The driving transistor DT may include a first node N1 electrically connected to the light emitting device ED, a second node N2 to which the data signal VDATA is applied, and a third node N3 to which the driving voltage VDD is applied from the first common driving voltage line VDDL.

In the driving transistor DT, the second node N2 may be a gate node, the first node N1 may be a source node or a drain node, and the third node N3 may be a drain node or a source node. Hereinafter, for convenience of explanation, it will be described a case in which the second node N2 is a gate node, the first node N1 is a source node, and the third node N3 is a drain node in the driving transistor DT.

The scan transistor ST included in the subpixel circuit SPC illustrated in FIG. 2 may be a switching transistor for transmitting a data signal VDATA, which is an image signal, to the second node N2 which is the gate node of the driving transistor DT.

The scan transistor ST may be controlled on-off by the scan signal SC which is a gate signal applied through the scan line SCL as a type of gate line GL, and may control the electrical connection between the second node N2 of the driving transistor DT and the data line DL. The drain electrode or source electrode of the scan transistor ST may be electrically connected to the data line DL, and the source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

If the display panel 110 has a top emission structure, at least a portion of the subpixel circuit SPC may overlap with at least a portion of the light emitting device ED in the vertical direction. Alternatively, if the display panel 110 has a bottom emission structure, the subpixel circuit SPC may not overlap with the light emitting device ED in the vertical direction.

As shown in FIG. 2, the subpixel circuit SPC may have 2T-1C structure including two transistors T1 and T2 and one capacitor Cst. In some case, the subpixel circuit SPC may further include one or more transistors or one or more capacitors.

For example, the subpixel circuit SPC may have a 8T-1C structure including eight transistors and a single capacitor. For another example, the subpixel circuit SPC may have a 6T-2C structure including six transistors and two capacitors. For another example, the subpixel circuit SPC may have a 7T-1C structure including seven transistors and one capacitor.

Depending on the structure of the subpixel circuit SPC, there may vary the type and number of gate signal and/or gate lines supplied to the subpixel SP.

In addition, depending on the structure of the subpixel circuit SPC, there may vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 may be disposed on the display panel 110 to prevent or at least reduce oxygen from penetrating into the circuit elements (particularly, the light emitting device ED). The encapsulation layer 200 may be configured in various shapes to prevent the light emitting device ED from coming into contact with moisture or oxygen.

Although not shown in Referring to FIG. 2, the display device 100 according to the embodiments of the present disclosure may further include a touch sensor layer including a plurality of sensor electrodes to sense a touch of an user, and a touch sensing circuit configured to sense the plurality of sensor electrodes to determine the presence or absence of a touch or touch coordinates.

The touch sensor layer may be built or embedded into the display panel 110. For example, the touch sensor layer may be disposed on an encapsulation layer 200 within the display panel 110.

The display panel 110 may include the touch sensor layer and also a plurality of touch pads to which the touch sensing circuit is electrically connected, and a plurality of touch routing lines for electrically connecting the plurality of sensor electrodes included in the touch sensor layer and the plurality of touch pads connected to the touch sensing circuit.

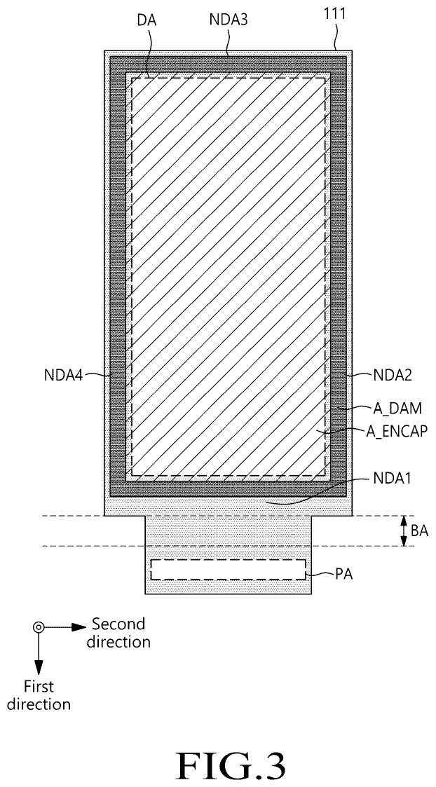

FIG. 3 illustrates a substrate 111 of a display panel 110 according to embodiments of the present disclosure.

Referring to FIG. 3, the substrate 111 of the display panel 110 according to the embodiments of the present disclosure may include a display area DA on which an image may be displayed and a non-display area NDA on which an image is not displayed.

Referring to FIG. 3, the non-display area NDA may include a first non-display area NDA1 located in a first direction from the display area DA, a second non-display area NDA2 located in a second direction from the display area DA, a third non-display area NDA3 located in a direction opposite to the first direction from the display area DA, and a fourth non-display area NDA4 located in a direction opposite to the second direction from the display area DA. For example, the first direction may be a column direction (e.g., Y-axis direction), and the second direction intersecting the first direction may be a row direction (e.g., X-axis direction).

Referring to FIG. 3, the first non-display area NDA1 may include a pad area PA in which a plurality of pads are disposed.

In the pad area PA, there may be disposed a plurality of pads to which a driving circuit is electrically connected. A plurality of driving circuits or printed circuit boards may be electrically connected. For example, the plurality of pads may include a plurality of display pads and a plurality of touch pads. A plurality of data lines, a first common driving voltage line VDDL, and a second common driving voltage line VSSL may be electrically connected to the plurality of display pads. A plurality of touch routing lines may be electrically connected to the plurality of touch pads.

Referring to FIG. 3, the first non-display area NDA1 may further include a bending area BA. In this case, the substrate 111 may be a flexible substrate. In some cases, the first non-display area NDA1 may not include a bending area BA.

Referring to FIG. 3, the display panel 110 may further include a ground line disposed in a non-display area NDA of the substrate 111. The ground line may be disposed from one point of the pad area PA to another point of the pad area PA via the second non-display area NDA2, the third non-display area NDA3 and the fourth non-display area NDA4.

Referring to FIG. 3, the display panel 110 may include an encapsulation layer area A_ENCAP and a dam area A_DAM.

Referring to FIG. 3, the encapsulation layer area A_ENCAP may be an area where the encapsulation layer 200 is disposed. In the display panel 110 according to the embodiments of the present disclosure, the encapsulation layer 200 may have a structure in which an inorganic film and an organic film are laminated. In this case, an edge of the encapsulation layer 200 may be considered as an edge of the organic film.

Referring to FIG. 3, the dam area A_DAM may be an area surrounding the encapsulation layer area A_ENCAP. A structure serving as a dam may be located in the dam area A_DAM. The dam may prevent the organic film in a liquid state from flowing out to the outside.

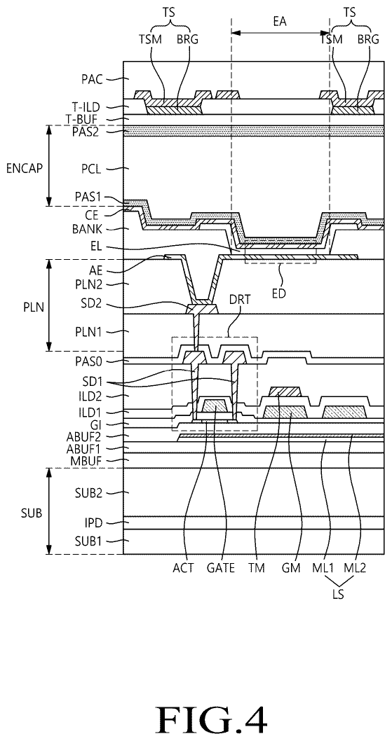

FIG. 4 is a cross-sectional view of the display area DA of the display panel 110 according to the embodiments of the present disclosure.

Referring to FIG. 4, the substrate SUB may include a first substrate SUB1, an interlayer insulating film IPD, and a second substrate SUB2. The interlayer insulating film IPD may be located between the first substrate SUB1 and the second substrate SUB2. The substrate SUB may be configured to include the first substrate SUB1, the interlayer insulating film IPD and the second substrate SUB2, thereby preventing or at least reducing moisture penetration. For example, the first substrate SUB1 and the second substrate SUB2 may be polyimide PI substrates. The first substrate SUB1 may be referred to as a primary PI substrate, and the second substrate SUB2 may be referred to as a secondary PI substrate.

Referring to FIG. 4, there may be disposed various patterns (e.g., ACT, SD1, GATE), various insulating films or insulating layers (e.g., MBUF, ABUF1, ABUF2, GI, ILD1, ILD2, PAS0), and various metal patterns (e.g., TM, GM, ML1, ML2) for forming transistors such as driving transistors DRT on the substrate SUB.

Referring to FIG. 4, a multi-buffer layer MBUF may be disposed on the second substrate SUB2, and a first active buffer layer ABUF1 may be disposed on the multi-buffer layer MBUF.

A first metal layer ML1 and a second metal layer ML2 may be disposed on the first active buffer layer ABUF1. Here, the first metal layer ML1 and the second metal layer ML2 may be a light shielding layer LS capable of blocking the light.

A second active buffer layer ABUF2 may be disposed on the first metal layer ML1 and the second metal layer ML2. An active layer ACT of a driving transistor DRT may be disposed on the second active buffer layer ABUF2.

A gate insulating film GI may be disposed while covering the active layer ACT.

A first gate electrode GATE1 of a driving transistor DRT may be disposed on the gate insulating film GI. In this case, a gate material layer GM may be disposed on the gate insulating film GI together with the first gate electrode GATE1 of the driving transistor DRT at a position different from the formation position of the driving transistor DRT.

A first interlayer insulating film ILD1 may be disposed while covering the first gate electrode GATE1 and the gate material layer GM. A metal pattern TM may be disposed on the first interlayer insulating film ILD1. The metal pattern TM may be located at a different location from the formation location of the driving transistor DRT. A second interlayer insulating film ILD2 may be disposed while covering the metal pattern TM on the first interlayer insulating film ILD1.

Two first source-drain electrode patterns SD1 may be disposed on the second interlayer insulating film ILD2. One of the two first source-drain electrode patterns SD1 may be a source node of the driving transistor DRT, and the other may be a drain node of the driving transistor DRT. The two first source-drain electrode patterns SD1 may be electrically connected to one side and the other side of the active layer ACT through the contact holes of the second interlayer insulating film ILD2, the first interlayer insulating film ILD1 and the gate insulating film GI.

A portion of the active layer ACT overlapping with the first gate electrode GATE1 may be a channel region. One of the two first source-drain electrode patterns SD1 may be connected to one side of the channel region in the active layer ACT, and the other of the two first source-drain electrode patterns SD1 may be connected to the other side of the channel region in the active layer ACT.

A passivation layer PASO may be disposed to cover the two first source-drain electrode patterns SD1. A planarization layer PLN may be disposed on the passivation layer PAS0. The planarization layer PLN may include a first planarization layer PLN1 and a second planarization layer PLN2.

The first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SD1 (corresponding to the second node N2 of the driving transistor DRT in the subpixel SP of FIG. 2) through the contact hole of the first planarization layer PLN1.

A second planarization layer PLN2 may be disposed while covering the second source-drain electrode pattern SD2. A light emitting device ED may be disposed on the second planarization layer PLN2.

In a stacked structure of the light emitting device ED, an anode electrode AE may be disposed on the second planarization layer PLN2. The anode electrode AE may be electrically connected to the second source-drain electrode pattern SD2 through a contact hole of the second planarization layer PLN2.

A bank BANK may be disposed to cover a part of the anode electrode AE. A part of the bank BANK corresponding to a light emission area EA of the subpixel SP may be opened.

A part of the anode electrode AE may be exposed to an opening (e.g., open portion) of the bank BANK. An emission layer EL may be located on a side of the bank BANK and in the opening (e.g., open portion) of the bank BANK. All or a part of the emission layer EL may be located between adjacent banks BANK.

In the opening of the bank BANK, the emission layer EL may be in contact with the anode electrode AE. A cathode electrode CE may be disposed on the emission layer EL.

A light emitting device ED may be formed by the anode electrode AE, the emission layer EL and the cathode electrode CE. The emission layer EL may include an organic film.

An encapsulation layer ENCAP may be disposed on the light emitting device ED.

The encapsulation layer ENCAP may have a single-layer structure or a multi-layer structure. For example, as illustrated in FIG. 4, the encapsulation layer ENCAP may include a first inorganic encapsulation layer PAS1, an organic encapsulation layer PCL and a second inorganic encapsulation layer PAS2.

For example, the first inorganic encapsulation layer PAS1 and the second inorganic encapsulation layer PAS2 may be inorganic films, and the organic encapsulation layer PCL may be an organic film. Among the first inorganic encapsulation layer PAS1, the organic encapsulation layer PCL, and the second inorganic encapsulation layer PAS2, the organic encapsulation layer PCL may be the thickest, and may act as a planarizing layer.

The first inorganic encapsulation layer PAS1 may be disposed on the cathode electrode CE, and may be disposed closest to the light emitting device ED. The first inorganic encapsulation layer PAS1 may be formed of an inorganic insulating material capable of low-temperature deposition. For example, the first inorganic encapsulation layer PAS1 may include silicon nitride (SiNx), silicon oxide (SiOx), silicon oxynitride (SiON), aluminum oxide (Al2O3), and the like. Since the first inorganic encapsulation layer PAS1 is deposited in a low-temperature atmosphere, the first inorganic encapsulation layer PAS1 may prevent or at lest reduce the emission layer EL including an organic material vulnerable to a high-temperature atmosphere from being damaged during the deposition process.

The organic encapsulation layer PCL may be formed with a smaller area than the first inorganic encapsulation layer PAS1. In this case, the organic encapsulation layer PCL may be formed to expose both ends of the first inorganic encapsulation layer PAS1. The organic encapsulation layer PCL may act as a buffer to relieve stress between each layer due to the bending of the display device 100, and may also act to enhance the flattening performance. For example, the organic encapsulation layer PCL may be made of an acrylic resin, an epoxy resin, a polyimide, polyethylene, or a silicon oxycarbon SiOC, and may be formed of an organic insulating material. For example, the organic encapsulation layer PCL may be formed through an inkjet process.

The second inorganic encapsulation layer PAS2 may be formed on the substrate SUB on which the organic encapsulation layer PCL is formed, so as to cover the upper surface and side surface of each of the organic encapsulation layer PCL and the first inorganic encapsulation layer PAS1. The second inorganic encapsulation layer PAS2 may minimize or block external moisture or oxygen from penetrating into the first inorganic encapsulation layer PAS1 and the organic encapsulation layer PCL. For example, the second inorganic encapsulation layer PAS2 may be formed of an inorganic insulating material such as silicon nitride (SiNx), silicon oxide (SiOx), silicon oxynitride (SiON), or aluminum oxide (Al2O3).

Referring to FIG. 4, if the touch sensor TS is of a type built into the display panel, the touch sensor TS may be disposed on the encapsulation layer ENCAP. The touch sensor structure will be described in detail as follows.

A touch buffer film T-BUF may be disposed on the encapsulation layer ENCAP. The touch sensor TS may be disposed on the touch buffer film T-BUF.

The touch sensor TS may include a touch sensor metal TSM and a bridge metal BRG located in different layers.

A touch interlayer insulating film T-ILD may be disposed between the touch sensor metal TSM and the bridge metal BRG.

For example, the touch sensor metal TSM may include a first touch sensor metal TSM, a second touch sensor metal TSM, and a third touch sensor metal TSM disposed adjacent to each other. If the third touch sensor metal TSM is located between the first touch sensor metal TSM and the second touch sensor metal TSM, and the first touch sensor metal TSM and the second touch sensor metal TSM are required to be electrically connected to each other, the first touch sensor metal TSM and the second touch sensor metal TSM may be electrically connected to each other through the bridge metal BRG located in a different layer. The bridge metal BRG may be insulated from the third touch sensor metal TSM by the touch interlayer insulating film T-ILD.

When the touch sensor TS is formed on the display panel PNL, there may be generated a chemical solution (e.g., developer solution or etchant, etc.) used in the process or moisture from the outside. Since the touch sensor TS is disposed on the touch buffer film T-BUF, there may prevent the chemical solution or moisture from penetrating into the emission layer EL containing an organic material during the manufacturing process of the touch sensor TS. Accordingly, the touch buffer film T-BUF may prevent damage to the emission layer EL vulnerable to the chemical solution or moisture.

The touch buffer film T-BUF may be formed at a low temperature condition below a specific temperature (e.g., 100° C.), and may be formed of an organic insulating material having a low permittivity of 1 to 3 in order to prevent damage to the emission layer EL containing an organic material which is vulnerable to high temperatures. For example, the touch buffer film T-BUF may be formed of an acrylic series, an epoxy series, or a siloxane series material. As the display device 100 bends, the encapsulation layer ENCAP may be damaged and the touch sensor metal positioned on the touch buffer film T-BUF may be broken or disconnected. Even if the display device 100 bends, the touch buffer film T-BUF having flattening performance made of an organic insulating material may prevent damage to the encapsulation layer ENCAP and/or breakage of the metal TSM or BRG forming the touch sensor TS.

A protective layer PAC may be disposed while covering the touch sensor TS. The protective layer PAC may be an organic insulating film. Although not shown in FIG. 4, an organic encapsulation layer (not shown) may be further disposed on an upper portion of the protective layer PAC.

Hereinafer, it will be described the inner dams DAM1 and outer dams DAM2 disposed in the dam area A_DAM of the display panel in more detail.

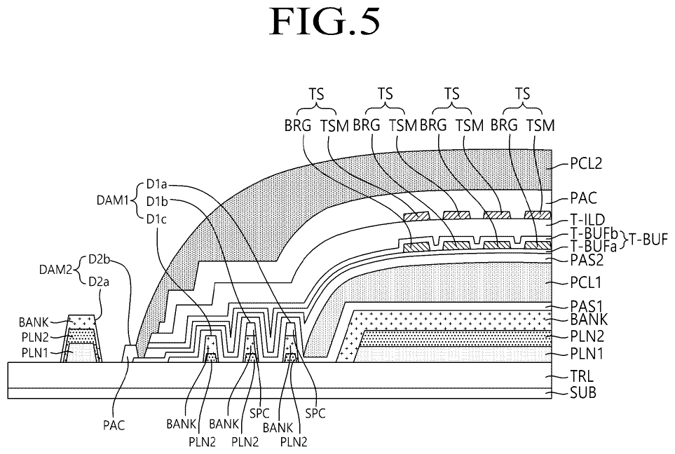

FIGS. 5, 6, and 7 are cross-sectional views of a display panel 110 including the inner dams DAM1 and outer dams DAM2 according to embodiments of the present disclosure.

Referring to FIG. 5, a substrate SUB may be disposed at the bottom of the display panel 110.

Referring to FIG. 5, a transistor layer TRL may be disposed on the substrate SUB. The transistor layer TRL may include various patterns (e.g., ACT, SD1, GATE1), various insulating films or insulating layers (e.g., MBUF, ABUF1, ABUF2, GI, ILD1, ILD2, PAS0) and various metal patterns (e.g., TM, GM, ML1, ML2) for forming the transistor illustrated in FIG. 4, and the transistor layer TRL is simply illustrated for convenience of explanation.

Referring to FIG. 5, a first planarization layer PLN1 may be disposed on the transistor layer TRL. After the first planarization layer PLN1 is entirly deposited on the transistor layer TRL, a portion of the first planarization layer PLN1 may be removed through an etching process.

A portion of the etched first planarization layer PLN1 may be included in a first outer dam D2a.

Referring to FIG. 5, a second planarization layer PLN2 may be disposed on an upper portion of the first planarization layer PLN1. After the second planarization layer PLN2 is entirly deposited on the first planarization layer PLN1, a portion of the second planarization layer PLN2 may be removed through an etching process.

A portion of the etched second planarization layer PLN2 may be included in the first outer dam D2a. A portion of the etched second planarization layer PLN2 may be disposed on the etched first planarization layer PLN1.

A portion of the etched second planarization layer PLN2 may be included in each of a first inner dam D1a, a second inner dam D1b, and a third inner dam D1c.

Referring to FIG. 5, a bank BANK may be disposed on an upper portion of the second planarization layer PLN2. After the bank BANK is entirly deposited on the second planarization layer PLN2, a portion of the bank BANK may be removed through an etching process.

A portion of the etched bank BANK may be included in the first outer dam D2a. Referring to FIG. 5, the first outer dam D2a may include a first planarization layer PLN1, a second planarization layer PLN2, and a bank BANK. The second planarization layer PLN2 of the first outer dam D2a may be disposed to cover the first planarization layer PLN1 of the first outer dam D2a. The bank BANK of the first outer dam D2a may be disposed to cover the second planarization layer PLN2 of the first outer dam D2a.

A portion of the etched bank BANK may be included in each of the first inner dam D1a, the second inner dam D1b, and the third inner dam D1c. The bank BANK of the first inner dam D1a may be disposed to cover the second planarization layer PLN2 of the first inner dam D1a. The bank BANK of the second inner dam D1b may be disposed to cover the second planarization layer PLN2 of the second inner dam D1b. The bank BANK of the third inner dam D1c may be disposed to cover the second planarization layer PLN2 of the third inner dam D1c.

Referring to FIG. 5, the first inner dam D1a may further include a spacer SPC. The spacer SPC of the first inner dam D1a may be disposed on the bank BANK of the first inner dam D1a.

Referring to FIG. 5, the second inner dam D1b may further include a spacer SPC. The spacer SPC of the second inner dam D1b may be disposed on the bank BANK of the second inner dam D1b.

Referring to FIG. 5, a first inorganic encapsulation layer PAS1 may be disposed to cover the bank BANK, the first inner dam D1a, the second inner dam D1b, and the third inner dam D1c. The first inorganic encapsulation layer PAS1 may be disposed in contact with the transistor layer TRL exposed by the etched bank BANK.

Referring to FIG. 5, a first organic encapsulation layer PCL1 may be disposed on the first inorganic encapsulation layer PAS1. The first organic encapsulation layer PCL1 may be formed using an inkjet method. In this case, the first organic encapsulation layer PCL1 may overflow out of the display panel 110. Referring to FIG. 5, since the inner dams DAM1 are formed before the first organic encapsulation layer PCL1 is disposed, the first organic encapsulation layer PCL1 may not overflow into the non-display area.

Referring to FIG. 5, the first inner dam D1a may be disposed on the outside of the first organic encapsulation layer PCL1. The second inner dam D1b may be disposed on the outside of the first inner dam D1a. The third inner dam D1c may be disposed on the outside of the second inner dam D1b.

Referring to FIG. 5, the first organic encapsulation layer PCL1 may be disposed in contact with the first inorganic encapsulation layer PAS1 disposed to overlap with the first inner dam D1a. The thickness of the first organic encapsulation layer PCL1 may be greater than the thickness of the first inorganic encapsulation layer PAS1 and the thickness of the second inorganic encapsulation layer PAS2.

Referring to FIG. 5, a second inorganic encapsulation layer PAS2 may be disposed to cover the first organic encapsulation layer PCL1 and the first inorganic encapsulation layer PAS1. The second inorganic encapsulation layer PAS2 may be disposed in contact with the first inorganic encapsulation layer PAS1 overlapping with the first inner dam D1a. The second inorganic encapsulation layer PAS2 may be disposed in contact with the first inorganic encapsulation layer PAS1 overlapping with the second inner dam D1b. The second inorganic encapsulation layer PAS2 may be disposed in contact with the first inorganic encapsulation layer PAS1 overlapping with the third inner dam D1c. The second inorganic encapsulation layer PAS2 may be disposed in contact with the substrate SUB beyond the first inorganic encapsulation layer PAS1 overlapping with the third inner dam D1c.

Referring to FIG. 5, a touch buffer film T-BUF may include a first touch buffer film T-BUFa and a second touch buffer film T-BUFb.

Referring to FIG. 5, the first touch buffer film T-BUFa may be disposed to cover the second inorganic encapsulation layer PAS2. The first touch buffer film T-BUFa may be an inorganic film.

Referring to FIG. 5, a bridge metal BRG may be disposed on the first touch buffer film T-BUFa. The bridge metal BRG may be disposed to overlap with a touch sensor metal TSM at a lower portion of the touch sensor metal TSM.

Referring to FIG. 5, the second touch buffer film T-BUFb may be disposed to cover the bridge metal BRG and the first touch buffer film T-BUFa. The second touch buffer film T-BUFa may be an inorganic film.

Referring to FIG. 5, a touch interlayer insulating film T-ILD may be disposed on the second touch buffer film T-BUFb. The touch interlayer insulating film T-ILD may be an inorganic film or an organic film. If the touch interlayer insulating film T-ILD is an organic film, the thickness of the touch interlayer insulating film T-ILD as an organic film may be greater than the thickness of the touch interlayer insulating film T-ILD which is an inorganic film.

Referring to FIG. 5, the touch sensor metal TSM may be disposed on the touch interlayer insulating film T-ILD. The touch sensor metal TSM may be disposed to overlap with the bridge metal BRG.

Referring to FIG. 5, a protective layer PAC may be disposed to cover the touch sensor metal TSM and the touch interlayer insulating film T-ILD. After the protective layer PAC is entirly deposited on the touch interlayer insulating film T-ILD, a portion of the protective layer PAC may be removed through an etching process.

Referring to FIG. 5, the protective layer PAC may be disposed to expose a portion of the touch interlayer insulating film T-ILD. A portion of the etched protective layer PAC may be disposed around an area where a portion of the touch interlayer insulating film T-ILD is exposed. A portion of the etched protective layer PAC may be referred to as a second outer dam D2b. The second outer dam D2b may be a portion of the etched protective layer PAC. However, the second outer dam D2b may be formed separately from a different material.

Referring to FIG. 5, the second outer dam D2b may be disposed in contact with a second organic encapsulation layer PCL2. If the second outer dam D2b is formed by etching a portion of the protective layer PAC, the second outer dam D2b may be composed of an organic material. However, even if the second outer dam D2b is formed separately, the second outer dam D2b may include an organic material. A side of the second outer dam D2b may be dispoded to be in contact with the second organic encapsulation layer PCL2.

Referring to FIG. 5, the second organic encapsulation layer PCL2 may be disposed on the protective layer PAC. The second organic encapsulation layer PCL2 may be formed using an inkjet method. In this case, the second organic encapsulation layer PCL2 may overflow out of the display panel 110. Referring to FIG. 5, since the outer dams DAM2 are formed before disposing the second organic encapsulation layer PCL2, the second organic encapsulation layer PCL2 may not overflow out of the display panel 110.

The second organic encapsulation layer PCL2 may be disposed to overlap with the side of the second outer dam D2b.

Referring to FIG. 5, a portion of the touch interlayer insulating film T-ILD may be exposed and disposed by the etched protective layer PAC, and the second organic encapsulation layer PCL2 may be disposed in contact with a portion of the second inorganic encapsulation layer PAS2, a portion of the touch buffer film T-BUF, and a portion of the touch interlayer insulating film T-ILD.

Referring to FIG. 5, the first organic encapsulation layer PCL1 and the second organic encapsulation layer PCL2 may be formed by an inkjet method. When the first organic encapsulation layer PCL1 is formed, the inner dams DAM1 may prevent the first organic encapsulation layer PCL1 from flowing out of the inner dams DAM1. When the second organic encapsulation layer PCL2 is formed, the outer dams DAM2 may prevent the second organic encapsulation layer PCL2 from flowing out of the outer dams DAM2.

Referring to FIG. 5, the first outer dam D2a may function as a dam capable of preventing the overflow of the second organic encapsulation layer PCL2, while also functioning as a crack stopper. The crack stopper may prevent or at least reduce cracks, which may occur when performing a cutting process for the display panel 110, from being transferred to the inside of the display panel 110. Since the first outer dam D2a functioning as a crack stopper also functions as a dam, the bezel size of the display panel 110 may be reduced.

Referring to FIG. 5, the first outer dam D2a may include all of the first planarization layer PLN1, the second planarization layer PLN2, and the bank BANK. Alternatively, the first outer dam D2a may include at least one of the first planarization layer PLN1, the second planarization layer PLN2, and the bank BANK.

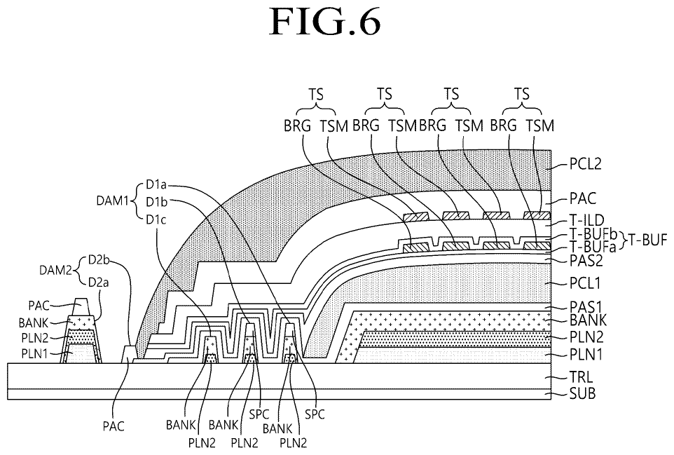

The first outer dam D2a may be disposed to be spaced apart from the second outer dam D2b. Referring to FIG. 6, the first outer dam D2a may further include a protective layer PAC. The protective layer PAC of the first outer dam D2a may be disposed on the bank BANK of the first outer dam D2a. Since the first outer dam D2a further includes a protective layer PAC, the height of the first outer dam D2a may be further increased.

Referring to FIG. 6, a height of the first outer dam D2a may be greater than a height of the second outer dam D2b. The protective layer PAC included in the first outer dam D2a may be formed simultaneously with the second outer dam D2b. That is, after the protective layer PAC is completely deposited, the protective layer PAC of the first outer dam D2a may be formed through an etching process. In addition, after the protective layer PAC is completely deposited, the second outer dam D2b may be formed through an etching process.

Meanwhile, the outer dams DAM2 and the inner dams DAM1 can be disposed in a first non-display area NDA1, a second non-display area NDA2, a third non-display area NDA3, and the fourth non-display area NDA4 illustrated in FIG. 4.

The first outer dam D2a may be disposed in the first non-display area NDA1. In this case, the first non-display area NDA1 may be an area where a plurality of pads are disposed. Since lines or wirings connected to the pads are disposed in the first non-display area NDA1, there may be difficult to form the first outer dam D2a. In this case, the first outer dam D2a of the first non-display area NDA1 may be formed of a protective layer PAC.

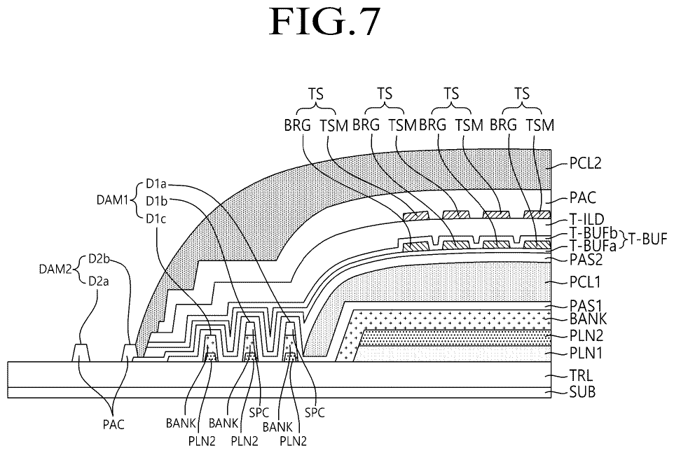

Referring to FIG. 7, there is illustrated a first outer dam D2a formed of an etched protective layer PAC. The first outer dam D2a formed of a protective layer PAC may have a height equal to or similar to a height of the second outer dam D2b.

The first outer dam D2a may be disposed spaced apart from the second outer dam D2b.

The embodiments of the first outer dam in FIG. 6 and FIG. 7 can be combined with each other. That is, the first outer dam D2a disposed in the second non-display area NDA2 may include at least one of the first planarization layer PLN1, the second planarization layer PLN2, and the bank BANK as shown in FIG. 6, and the first outer dam D2a disposed in the first non-display area NDA1 may include a protective layer PAC as shown in FIG. 7.

According to embodiments of the present disclosure, it is possible to provide a display device including an outer dam capable of reducing a bezel size.

According to embodiments of the present disclosure, it is possible to provide a display device capable of preventing an organic encapsulation layer from overflowing through an outer dam.

According to embodiments of the present disclosure, it is possible to provide a display device capable of preventing or at least reducing crack formation by using an outer dam.

According to embodiments of the present disclosure, it is possible to provide a display device capable of increasing process efficiency by using an outer dam functioning as a dam and a crack stopper.

Embodiments of the present disclosure described above are briefly described as follows.

A display device according to embodiments of the present disclosure may include a substrate including a display area and a non-display area, a first planarization layer disposed on the substrate, a second planarization layer disposed on the first planarization layer, a bank disposed on the second planarization layer, a first encapsulation layer disposed on the bank, a touch sensor disposed on the first encapsulation layer, a second encapsulation layer disposed on the touch sensor, and a first outer dam disposed on an outer side of the second encapsulation layer, and including at least one of the first planarization layer, the second planarization layer, and the bank.

The first outer dam may include the bank, and a protective layer disposed on the bank, and the protective layer may be disposed between the touch sensor and the second encapsulation layer.

The display device according to embodiments of the present disclosure may further include a second outer dam disposed on the outer side of the second encapsulation layer and in contact with the second encapsulation layer. A height of the first outer dam may be greater than a height of the second outer dam.

The display device according to embodiments of the present disclosure may further include a second outer dam disposed in the non-display area, and the second outer dam may include a protective layer disposed between the touch sensor and the second encapsulation layer.

The display device according to embodiments of the present disclosure may further include a protective layer disposed to cover the touch sensor and disposed between the touch sensor and the second encapsulation layer, and a second outer dam including the protective layer and disposed at an outer side of the second encapsulation layer and in contact with the second encapsulation layer.

The first outer dam may be spaced apart from the second outer dam, and the first outer dam may be disposed outside the second outer dam with respect to the display area.

A height of the first outer dam may be greater than a height of the second outer dam.

The second outer dam may be disposed apart from the protective layer between the touch sensor and the second encapsulation layer.

The display device according to embodiments of the present disclosure may further include a first inner dam disposed on an outer side of an organic encapsulation layer included in the first encapsulation layer, and a second inner dam disposed on an outer side of the first inner dam. The first outer dam may be disposed outside the first inner dam and the second inner dam with respect to the display area.

A height of the first inner dam may be greater than a height of the second inner dam.

The first inner dam may include the bank and a spacer disposed on the bank.

The second encapsulation layer may be an organic insulating film.

The second encapsulation layer may include one of acrylic resin, epoxy resin, polyimide, polyethylene, or siliconoxycarbon.

The second encapsulation layer may be formed through an inkjet process.

The display device according to embodiments of the present disclosure may further include an emission layer disposed below the touch sensor.

The first outer dam may be disposed on an outer side of the first encapsulation layer.

A display device according to embodiments of the present disclosure may include: a substrate including a display area and a non-display area; a first planarization layer disposed on the substrate; a second planarization layer disposed on the first planarization layer, a bank disposed on the second planarization layer; a first encapsulation layer disposed on the bank; a touch sensor disposed on the first encapsulation layer; a protective layer disposed on the touch sensor; a second encapsulation layer disposed on the protective layer; and a first outer dam disposed on an outer side of the second encapsulation layer, wherein the first outer dam includes the protective layer.

The non-display area may include a first non-display area on which a plurality of pads are disposed and a second non-display area different from the first non-display area, and the first outer dam may be disposed in the first non-display area.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device comprising:
a substrate including a display area and a non-display area;
a first planarization layer on the substrate;
a second planarization layer on the first planarization layer;
a bank on the second planarization layer,
a first encapsulation layer on the bank;
a touch sensor on the first encapsulation layer;
a second encapsulation layer on the touch sensor; and
a first outer dam on an outer side of the second encapsulation layer, the first outer dam including at least one of the first planarization layer, the second planarization layer, and the bank.

2. The display device of claim 1, wherein the first outer dam further includes the bank, and a protective layer on the bank,
wherein the protective layer is between the touch sensor and the second encapsulation layer.

3. The display device of claim 2, further comprising:
a second outer dam in contact with the second encapsulation layer on the outer side of the second encapsulation layer,
wherein a height of the first outer dam is greater than a height of the second outer dam.

4. The display device of claim 1, further comprising:
a second outer dam in the non-display area, the second outer dam including a protective layer between the touch sensor and the second encapsulation layer.

5. The display device of claim 1, further comprising:
a protective layer covering the touch sensor, the protective layer between the touch sensor and the second encapsulation layer; and
a second outer dam including the protective layer, the second outer dam in contact with the second encapsulation layer at the outer side of the second encapsulation layer.

6. The display device of claim 5, wherein the first outer dam is spaced apart from the second outer dam,
wherein the first outer dam is outside the second outer dam with respect to the display area.

7. The display device of claim 5, wherein a height of the first outer dam is greater than a height of the second outer dam.

8. The display device of claim 5, wherein the second outer dam is disposed apart from the protective layer between the touch sensor and the second encapsulation layer.

9. The display device of claim 1, further comprising:
a first inner dam on an outer side of an organic encapsulation layer included in the first encapsulation layer; and
a second inner dam on an outer side of the first inner dam,
wherein the first outer dam is outside the first inner dam and the second inner dam with respect to the display area.

10. The display device of claim 9, wherein a height of the first inner dam is greater than a height of the second inner dam.

11. The display device of claim 9, wherein the first inner dam includes the bank and a spacer on the bank.

12. The display device of claim 1, wherein the second encapsulation layer is an organic insulating film.

13. The display device of claim 12, wherein the second encapsulation layer includes one of acrylic resin, epoxy resin, polyimide, polyethylene, or siliconoxycarbon.

14. The display device of claim 12, wherein the second encapsulation layer is formed through an inkjet process.

15. The display device of claim 1, further comprising:
an emission layer below the touch sensor.

16. The display device of claim 1, wherein the first outer dam is on an outer side of the first encapsulation layer.

17. A display device comprising:
a substrate including a display area and a non-display area;
a first planarization layer disposed on the substrate;
a second planarization layer disposed on the first planarization layer;
a bank disposed on the second planarization layer;
a first encapsulation layer disposed on the bank;
a touch sensor disposed on the first encapsulation layer,
a protective layer disposed on the touch sensor,
a second encapsulation layer disposed on the protective layer; and
a first outer dam disposed on an outer side of the second encapsulation layer, wherein the first outer dam includes the protective layer.

18. The display device of claim 17, wherein the non-display area includes a first non-display area on which a plurality of pads are disposed and a second non-display area different from the first non-display area, and the first outer dam is disposed in the first non-display area.
